(19) United States
(12) Patent Application Publication
(10) Pub. No.: US 2026/0282269 A1
(43) Pub. Date: Sep. 17, 2026

(54) AIRFLOW GUIDE THERMAL PAD FOR FLEX COOLING

(71) Applicant: Lenovo (United States) Inc., Morrisville, NC (US)

(72) Inventors: Hao-Yu Wang, Kanagawa (JP); Yuki Saigusa, Kanagawa (JP); Akinori Uchino, Kanagawa (JP); Masahiro Kitamura, Kanagawa (JP); Takuroh Kamimura, Kanagawa (JP)

(73) Assignee: Lenovo (United States) Inc., Morrisville, NC (US)

(21) Appl. No.: 19/081,545

(22) Filed: Mar. 17, 2025

(51) Int. Cl. H05K 7/20; G06F 1/20

(52) U.S. Cl. CPC H05K 7/20145; G06F 1/203; H05K 7/20154; H05K 7/20172; G06F 2200/201

(57) ABSTRACT

A computing device includes: a chassis; a heat generating element connected to a substrate within the chassis; and a heat management system configured to cool the heat generating element. The heat management system includes: a heat conductor that is thermally connected to the heat generating element; two fans configured to discharge air across the heat conductor; and an airflow guide disposed between the two fans in a width direction of the chassis. The airflow guide thermally connects the heat conductor to the chassis.

### TECHNICAL FIELD

The present disclosure relates to a method of fan cooling a computing device.

### BACKGROUND

Computing devices (e.g., laptop computers) include heat generating elements (e.g., central processing unit (CPU), graphics processing unit (GPU)) that must be cooled to maintain health and performance of the computing device. Typically, to achieve this cooling, a heat exchanger (e.g., heat sink) transfers the excess heat from the heat generating elements to a medium (e.g., intake air) that is conveyed away from the heat generating elements. For example, one or more fans may pull cooler external air into the computing device and exhaust the heat laden air out of the computing device. However, the airflow within the computing device may adversely affect user experience (e.g., vibration from the fan or airflow, heat transfer to other components, noise). Efficient methods of managing airflow and heat are required to ensure optimal performance and user experience of the computing device.

### SUMMARY

In general, one or more embodiments of the invention relate to a computer device comprising: a chassis; a heat generating element connected to a substrate within the chassis; and a heat management system configured to cool the heat generating element. The heat management system includes: a heat conductor that is thermally connected to the heat generating element; two fans configured to discharge air across the heat conductor; and an airflow guide disposed between the two fans in a width direction of the chassis. The airflow guide thermally connects the heat conductor to the chassis.

Other aspects of the invention will be apparent from the following description and the appended claims.

### BRIEF DESCRIPTION OF DRAWINGS

FIG. 1A shows a perspective view of a computing device in accordance with one or more embodiments of the invention.

FIG. 1B shows a top view schematic of various subcomponents of the computing device of FIG. 1A in accordance with one or more embodiments of the invention.

FIG. 2A shows a bottom view schematic of internal structures in the chassis of the computing device in accordance with one or more embodiments of the invention.

FIG. 2B shows a bottom view schematic of a heat conductor in accordance with one or more embodiments of the invention.

FIGS. 3A-3C show plan view schematics of example airflow guides 36 in accordance with one or more embodiments of the invention.

FIG. 4 shows a side view schematic of the internal structures in the chassis of the computing device in accordance with one or more embodiments of the invention.

FIG. 5 shows results of a comparative heat transfer experiment.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

To improve user experience of a computing device, such as a laptop computer, several factors are considered. Because a user often interacts with the laptop computer via an integrated keyboard, the sensory experience of the keyboard (e.g., the tactile feel and the temperature of the keys) is a key factor of consideration. As described in further detail below, embodiments of the present invention improve the sensory experience of the keyboard while simultaneously supporting the heat management systems of the computing device.

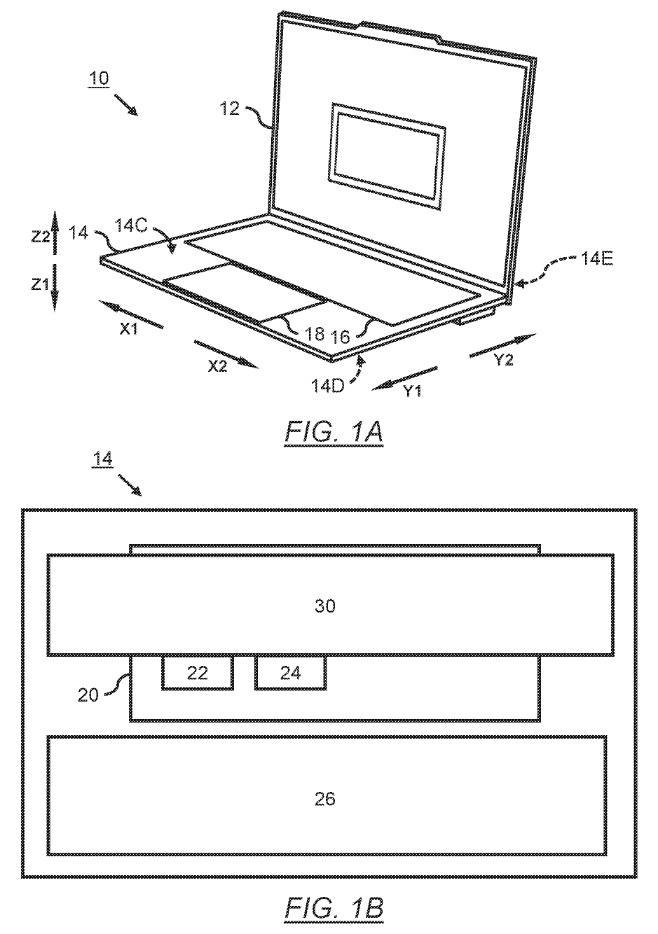

FIG. 1A shows a perspective view of a computing device 10 in accordance with one or more embodiments of the invention.

The computing device 10 (e.g., laptop personal computer (PC), tablet PC, desktop PC, convertible PC) is equipped with at least one heat generating device (e.g., a processor, an electronic component (e.g., resistor, transistor, capacitor, inductor, transformer)). Embodiments of the invention may be implemented on virtually any type of computing device 10, regardless of the platform being used. For example, the computing device 10 may be one or more mobile devices (e.g., laptop computer, smart phone, personal digital assistant, tablet computer, or other mobile device), desktop computers, servers, blades in a server chassis, or any other type of computing device.

The computing device 10 includes a screen body 12 and a chassis 14 that are connected by a hinge. Although the present embodiment illustrates the computing device 10 as a laptop PC, the computing device may alternatively be, for example, a tablet PC, a smartphone, or a portable game machine other than the laptop PC.

In one or more embodiments, the chassis 14 is a rectilinear box that extends in three orthogonal directions. For example, the chassis 14 may be a thin, flat box that extends in a width direction (e.g., an X-direction, in a first width direction X1, in a second width direction X2 opposite to the first width direction X1), a depth direction (e.g., a Y-direction, in a first depth direction Y1, in a second depth direction Y2 opposite to the first depth direction Y1), and a height direction (e.g., a Z-direction, in a first height direction Z1, in a second height direction Z2 opposite to the first height direction Z1). These directions are examples, and may change depending on the orientation and/or usage state of the computing device 10.

The chassis 14 may include a top cover 14C (i.e., a C-cover) and a bottom cover 14D (i.e., a D-cover) opposite to the top cover 14C in a thickness direction of the chassis 14. The chassis 14 may includes side walls that extend from the top cover 14C, that extend from the bottom cover 14D, or that are independent of the top cover 14C and/or the bottom cover 14D. The chassis 14 may include one or more user input devices, such as a keyboard 16 and/or a touchpad 18. Furthermore, the chassis 14 includes an exhaust port 14E that connects an interior space of the chassis 14 to the exterior of the computing device 10.

In one or more embodiments, the top cover 14C comprises a frame that forms an upper surface of the chassis 14 and four peripheral side surfaces while the bottom cover 14D is a cover plate that connects to the frame to enclose the lower surface of the chassis 14.

FIG. 1B shows a schematic of various subcomponents of the computing device 10 of FIG. 1A in accordance with one or more embodiments of the invention.

Within the chassis 14, the computing device 10 includes a substrate 20 (e.g., a circuit board, a motherboard) connected to a plurality of subcomponents. The subcomponents connected to the substrate 20 may include a central processing unit (CPU) 22, a graphics processing unit (GPU) 24 (e.g., a video subsystem), a memory, a chipset, a firmware memory, an embedded controller, a power components (e.g., charge circuit), and a storage device (e.g., hard disk drive (HDD), a solid state drive (SSD)), a communication device (e.g., transceiver, port), a battery 26. In one or more embodiments, the above subcomponents of the computing device 10 may be omitted, included in multiple quantities, combined as a single subcomponent (e.g., a processor that acts as a controller of one or more subcomponents), and/or disposed in other portions of the computing device 10.

One or more of the subcomponents on the substrate 20 may be a heat generating element. In one or more embodiments, the CPU and the GPU of the computing device generate the largest amount of subcomponents mounted on the substrate 20. It will be appreciated that other subcomponents beyond those listed above may be a heat generating element of the computing device 10 without departing from the scope of the present disclosure. For example, while the following embodiments are described with respect to a processor (e.g., a CPU, a GPU) on a motherboard, the invention may be directed to any type of heat generating element of the computing device 10.

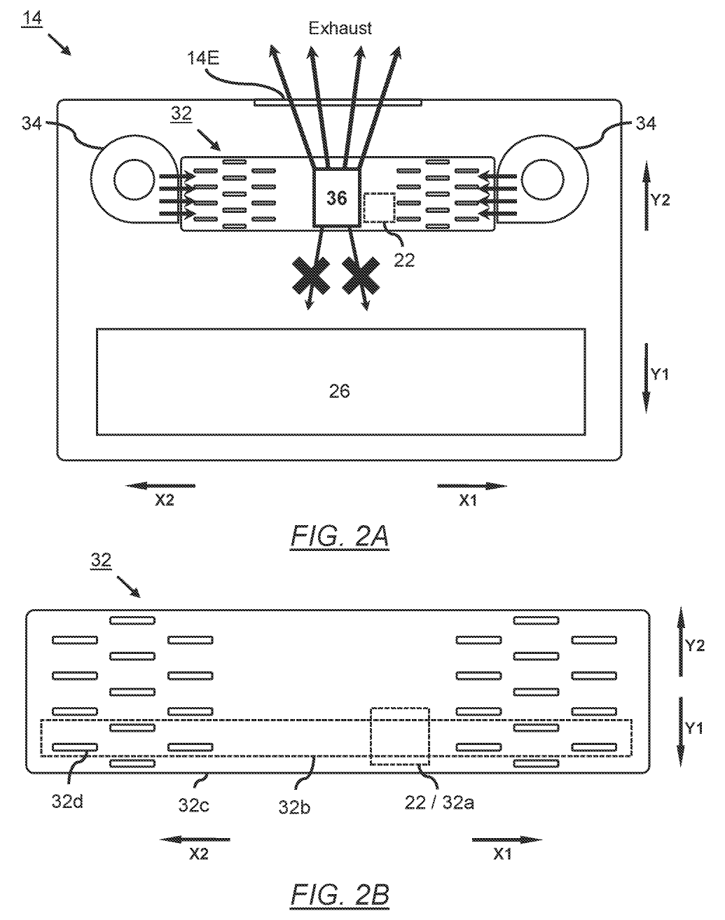

To manage heat generated by one or more heat generating elements of the computing device 10, a heat management system 30 can absorb, diffuse, and discharge the heat to the outside of the chassis 14. The heat management system 30 is described in further detail below with respect to FIG. 2.

FIG. 2A shows a bottom view schematic of internal structures in the chassis 14 of the computing device 10 in accordance with one or more embodiments of the invention.

As discussed above, the chassis 14 may include one or more exhaust ports 14E that connect the interior space of the chassis 14 to the exterior of the computing device 10. Heat from the heat generating elements of the computing device 10 can be dissipated by flowing air from the interior space of the chassis 14 to the exterior of the computing device 10 via at least one exhaust port 14E.

A heat management system 30 can actively and/or passively regulate the temperature and thermal characteristics of the computing device 10 with airflow out of the exhaust port 14E. The heat management system 30 comprises a heat conductor 32, one or more fans 34, and an airflow guide 36. Each of these components are described in further detail below.

FIG. 2B shows a bottom view schematic of a heat conductor 32 in accordance with one or more embodiments of the invention.

In one or more embodiments, the heat conductor 32 includes one or more heat sinks 32a, one or more heat pipes 32b, a heat diffuser 32c. In some embodiments, the heat conductor further includes protrusions 32d disposed on the heat diffuser 32c. Each of these components are described in further detail below.

A heat sinks 32a is heat transport device that thermally connects one or more corresponding heat generating elements to the heat conductor 32. In a plan view, each heat sink 32a is provided at a position corresponding to a heat generating element on the substrate 20. Each heat sink 32a may be a metal structure (e.g., a copper block), a vapor chamber, or any other structure that physically and thermally connects the corresponding heat generating element to another element of the heat conductor 32.

A heat pipe 32b is a heat transport device that thermally connects one or more heat sinks 32a to the heat diffuser 32c. For example, a heat pipe 32b may connect to multiple heat sinks 32a (e.g., corresponding to CPU 22 and GPU 24) on a lower side (Z1-facing side) of the heat pipe 32b and to the heat diffuser 32c on the upper side (Z2-facing surface). In a plan view, the heat pipe 32b may partially overlap with the heat sinks 32a and/or the heat generating elements to provide a direct thermal pathway (in the Z-direction) between the heat generating elements and the heat diffuser 32c.

Each heat pipe 32b comprises metal pipes that seal in a working fluid in an internal cavity. The metal pipes may have any cross-sectional shape. Examples of a working fluid include water, alternative fluorocarbons, acetone, butane, any fluid with an appropriate heat capacity, or any combination thereof.

A heat diffuser 32c is a heat exchange device that is thermally connected to the heat generating elements via the heat pipe 32b and heat sink 32a. The heat diffuser 32c can absorb and diffuse the heat from the heat pipe 32b across a large area to increase heat exchange efficiency with air inside the chassis 14.

The heat diffuser 32c includes a thin plate with high thermal conductivity. While the present disclosure relates to a copper metal plate as the heat diffuser 32c, it will be appreciated that any material with a thermal conductivity that meets the heat diffusion requirements of the computing system 10 may be used (e.g., aluminum). In one or more embodiments, the heat diffuser 32c includes a vapor chamber. Similar to the heat pipes 32b, a vapor chamber is a seal space that retains a working fluid. If present, protrusions 32d increase a surface area (internal and/or external) of the heat diffuser 32c to improve heat exchange efficiency. In some embodiments, the protrusions 32d may be fins, bumps, indentations, ridges, etc.

Returning to FIG. 2A, the fans 34 of the of the heat management system 30 supply air as a heat exchange medium to the heat conductor 32. Airflow produced by the fans 34 flows through the interior of the chassis 14 to cool the contents therein (e.g., the substrate 20 and subcomponents, the heat conductor 32, the battery 26). The airflow is directed to the outside of the chassis 14 through the exhaust port 14E (e.g., opening(s) formed in the chassis 14).

In one or more embodiments, the fans 34 are provided opposite ends of the heat conductor 32. Upper and/or lower surfaces of the fans 34 may include openings that are intake ports. For example, the fans 34 may draw air from the exterior of the chassis 14 via an opening in the chassis 14 and/or from a region of the interior space of the chassis. The fans 34 discharge the air through discharge ports directed toward the heat conductor 32. As discussed above, the heat diffuser 32c acts a heat exchanger to transfer the heat drawn from the heat generating elements to the air discharged from the fans 34.

The fans 34 may be centrifugal fans with motors that rotate impellers to discharge air in the plane perpendicular to the axis of rotation in the motor. As shown in FIG. 2A, the discharge ports of the fans 34 may oppose each other to send air along the +/-X-direction, across the longer axis of the heat conductor 32. The fans 34 may discharge air on one or both sides of the heat conductor 32 and/or the substrate 20 in the Z-direction (e.g., exchanging heat with any of the heat generating elements, heat sinks 32a, heat pipe 32b, heat diffuse 32c). While the disclosure relates to centrifugal fans, any appropriate fan configuration or air flow generating device may be used without departing from the disclosure.

As shown in FIG. 2A, the airflow guide 36 of the heat management system 30 directs the airflow generated by the fans 34 toward the exhaust port 14E. The airflow guide 36 is disposed between the two fans 34 in a width direction of the chassis 14. In one or more embodiments, the airflow guide 36 partially or entirely prevents airflow from the fans 34 from being redirected further into the chassis 14. Thus, the heat transferred from the heat conductor 32 to the air within the chassis 14 is more efficiently dissipated to the exterior of the computing device 10.

The airflow guide 36 comprises a pad of thermal rubber. For example, the thermal rubber may be a highly conformable, non-flammable, insulating silicone compound with a heat conductivity greater than or equal to a predetermined threshold based on thermal design point requirements of the computing device 10. The predetermined threshold may be 2.5 W/m*K. In one or more embodiments, the airflow guide 36 is a compound structure that include the thermal rubber material and a support structure (e.g., hardened silicone surface for improved handling, mesh reinforcement, any combination of structures).

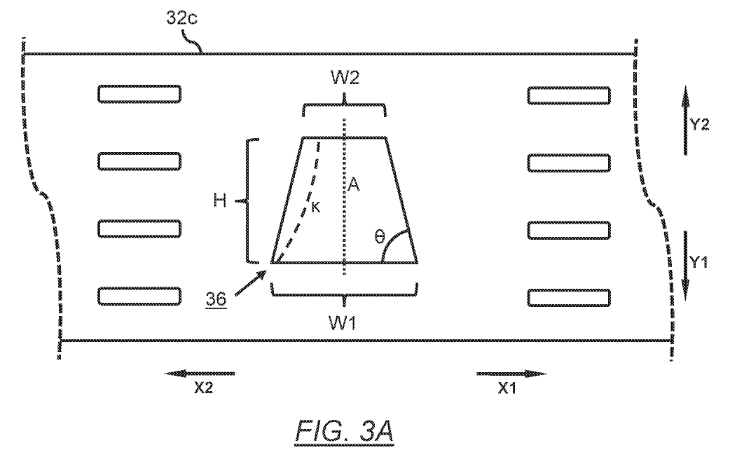

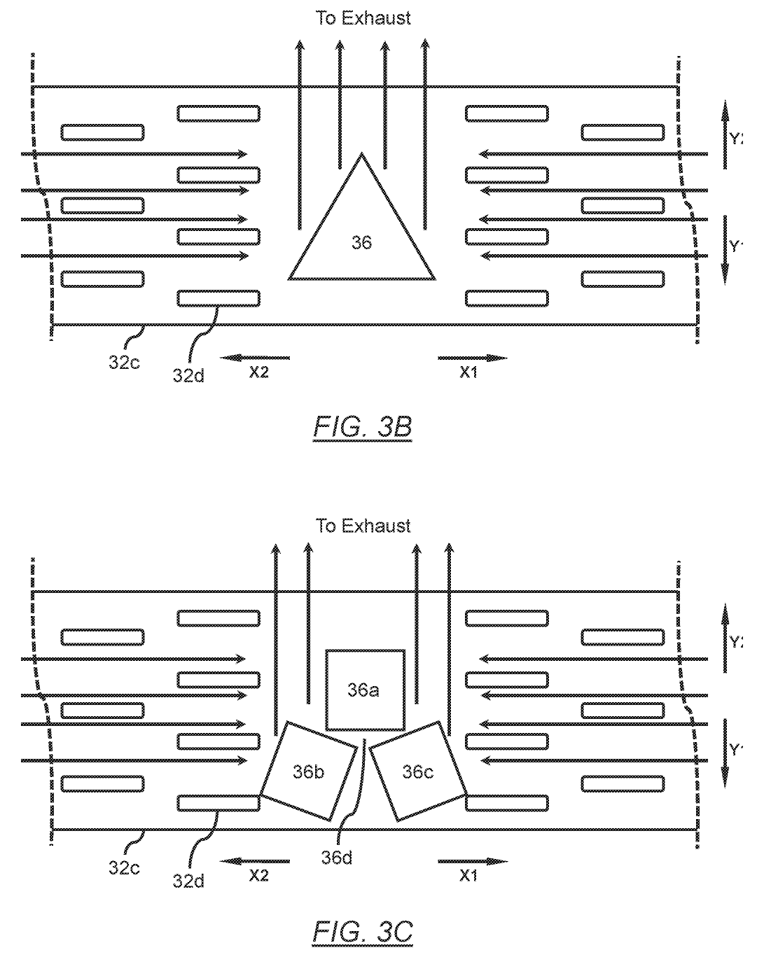

The airflow guide 36 is described in further detail below with respect to FIGS. 3-5.

FIGS. 3A-3C show plan view schematics of example airflow guides 36 in accordance with one or more embodiments of the invention.

The airflow guide 36 may be a thermal rubber pad with a side surface that is inclined with respect to an airflow direction of one or more of the fans 34. For example, a side surface on the X1 or X2 side of the airflow guide 36 may be inclined by an angle θ with respect to the airflow from fans 34 and/or the X-direction of the chassis 14. Each side may be inclined at a different angle with respect to the airflow from fans 34 and/or the X-direction of the chassis 14. In one or more embodiments, a side surface of the airflow guide 36 may have a curvature k to promote a more aerodynamic airflow from the X-direction discharge by the fans 34 to the Y-direction flow out of the exhaust port 14E.

In one or more embodiments, a width W1 of the side surface on the Y1 side of the airflow guide 36 may be less than a width W2 of the side surface on the Y2 side of the airflow guide 36. In other words, in a plan view of the heat conductor 32, the airflow guide 36 may have a tapered shape such that the width W2 of the airflow guide 36 on a side closer to the exhaust port 14E is smaller than the width W2 of the airflow guide 36 on a side farther from the exhaust port 14E. The asymmetry in the Y-direction of the airflow guide 36 may be designed to bias the airflow from the fans 34 toward the exhaust port 14E (e.g., in the Y2 direction).

In one or more embodiments, the airflow guide 36 is symmetric about an axis A in the Y-direction. Accordingly, airflow from each of the fans 34 on opposite sides of the computing device 10 may be equally redirected toward the exhaust port 14E to prevent turbulence in the internal space of the chassis 14.

In one or more embodiments, a height H of the airflow guide 36 in the Y-direction may be greater than or equal to a predetermined portion of the length of the heat conductor 32 or heat diffuser 32c in the Y-direction. The height H of the airflow guide 36 in the Y-direction may be greater than or equal to a predetermined portion of the length of the exhaust port of the fans 34 in the Y-direction. The height H and position (i.e., offset distance from one or both edges of heat diffuser 32c) of the airflow guide 36 in the Y-direction prevents direct collision between the airflow from each of the fans 34. Preventing airflow collision minimizes turbulence within internal space of the chassis 14 and improves the flow of heated air out of the exhaust port 14E.

As shown in FIG. 3B, in one or more embodiments, both sides surfaces on the X1 and X2 sides of the airflow guide 36 are inclined with respect to an airflow direction of the fans 34. For example, the thermal rubber pad may have a triangular shape. In a plan view of the heat conductor 32, the airflow guide 36 (e.g., a geometric center, a center of mass) may be disposed farther from the exhaust port 14E than a center of the heat conductor 32 in the Y-direction.

As shown in FIG. 3C, in one or more embodiments, the airflow guide 36 includes a plurality of thermal rubber pads. For example, the airflow guide 36 may include three thermal rubber pads 36a-c disposed in a triangular pattern. The thermal rubber pads may square pads oriented such that a side surface thereof is inclined with respect to the airflow from fans 34 and/or the X-direction of the chassis 14. In one or more embodiments, the plurality of thermal pads may be disposed to form an airflow gap 36d therebetween.

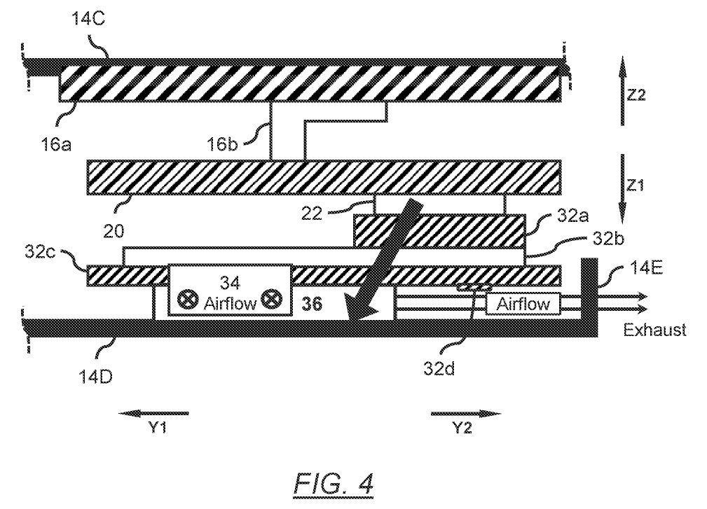

FIG. 4 shows a side view schematic of the internal structures in the chassis 14 of the computing device 10 in accordance with one or more embodiments of the invention.

Various pathways physically connect different components and subcomponents within the internal space of the chassis 14 of the computing device 10. Both direct and indirect physical connections between components may affect user experience. For example, airflow generated by the fans 34 of the heat management system 30 may produce vibrations on the keyboard 16. Minimizing vibration of the keyboard 16 improves the user experience of the computing device 10.

As shown in FIG. 4, some of the heat generating elements of the computing device 10 and the heat management system 30 are disposed on one side of the substrate 20. For example, the CPU 22 is mounted on the Z1-side of a motherboard 20 and the heat management system 30 is directly connected (physically and thermally) to the CPU 22. the keyboard 16 is disposed on the Z2-side of the substrate 20 (opposite side from the CPU 22). For example, a keyboard bracket 16b may physically connect the motherboard 20 to a keyboard surface 16a operated by a user on the Z2-side of the chassis 14. Vibrations from a motor of the fan 34 and/or vibrations caused by airflow on/around the substrate 20 and the heat management system 30 may be felt through these physical connections.

In addition to the aerodynamic properties above, the airflow guide 36 of the heat management system 30 may be configured to dampen vibrations in the chassis 14 to improve the user experience of computing device 10.

In one or more embodiments, a thickness of the airflow guide 36 in the Z-direction may be large enough to physically connect the heat conductor 32 with the chassis 14. In other words, in addition to thermally connecting the heat conductor 32 to the bottom cover 14D of the chassis 14, the airflow guide 36 may also physically connect the heat conductor 32 to the bottom cover 14D of the chassis 14. For example, the airflow guide 36 may be adhered to a Z1-side of the heat conductor 32 during fabrication of the heat management system 30 and compressed by the Z2-side of the bottom cover 14D when installed on the chassis 14. Alternatively, the airflow guide 36 may be adhered to the Z2-side of the bottom cover 14D and compressed by the heat conductor 32 during installation of the bottom cover 14D. A direct physical connection between the heat management system 30 and the chassis 14, via the airflow guide 36, may reduce the amplitude of vibrations transmitted to the keyboard 16 via the substrate 20.

In one or more embodiments, a hardness value of a material forming the airflow guide 36 is less than a predetermined threshold. In other words, a stiffness of the airflow guide 36 may be low enough to allow the airflow guide 26 to absorb a portion of the vibrations in the computing device 10 and further reduce the amplitude of vibrations transmitted to the keyboard 16 via the substrate 20.

In one or more embodiments, a location of the airflow guide 36 relative to another internal component of the computing device 10 may configured to reduce vibrations transmitted to the keyboard 16 via the substrate 20. For example, the airflow guide 36 may be disposed at a vibrational anti-node of the heat diffuser 32c to dampen vibrations of the heat conductor 32. The airflow guide may be disposed symmetrically or asymmetrically between two fans 34 of the heat management system 30 to dampen both fans 34 evenly or unevenly, respectively.

Furthermore, the location of the airflow guide 36 relative to another internal component of the computing device 10 may configured to improve thermal characteristics of the computing device 10. By stacking two or more of these components of the heat management system 30 in the thickness direction of the chassis (i.e., Z-direction), a direct thermal pathway may be formed between the chassis 14 and a heat generating element of the computing device 10. Accordingly, heat may be efficiently dissipated from the heat generating element to maintain its performance. In addition, heat may be efficiently directed to specific portions of the computing device 10 to improve the user experience.

In one or more embodiments, the airflow guide 36 may at least partially overlap the heat pipe 32b that is thermally connected to the heat generating element (e.g., CPU 22) in a thickness direction of the chassis 14. In one or more embodiments, the airflow guide 36 may at least partially overlaps a heat sink 32a connected to the heat generating element (e.g., CPU 22) in a thickness direction of the chassis 14. In one or more embodiments, the airflow guide 36 may at least partially overlaps the heat generating element (e.g., CPU 22) in a thickness direction of the chassis 14.

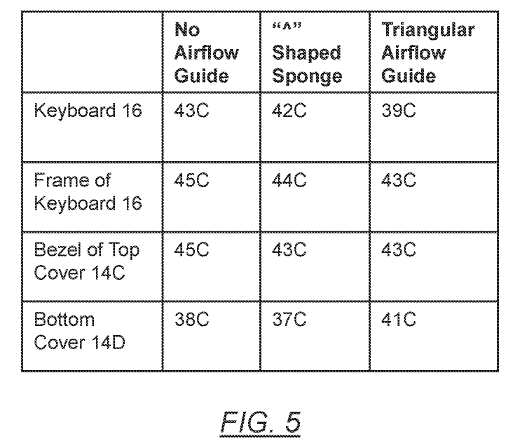

FIG. 5 shows results of a comparative heat transfer experiment.

The chart shown in FIG. 5 describes the results of a comparative heat transfer experiment on between configurations of a computing device 10 without an airflow guide, with a “^” shaped sponge (i.e., an insulating foam pad with approximately triangular outer geometry), and with an example triangular airflow guide 36 in accordance with one or more embodiments. In the experiment, the temperature on the keyboard 16, on a frame of the keyboard 16, on a bezel of the top cover 14C, and on the bottom cover 14D of the computing device 10 were measured.

The results indicate that the example airflow guide 36 routes heat away from the keyboard 16 more efficiently and reduces the temperature experienced by the fingertips of user of the computing device 10. While this is accompanied by a relative increase in heat transfer to the bottom cover 14D (compared to the control configuration and the “^” shaped sponge configuration), the mild increase in temperature at the bottom cover 14D is well within target specifications.

Although the disclosure has been described with respect to a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE NUMERALS

10 computing device

12 screen body

14 chassis

14C top cover

14D bottom cover

14E exhaust port

16 keyboard

18 touchpad

20 substrate

22 CPU

24 GPU

26 battery

30 heat management system

32 heat conductor

32a heatsink

32b heat pipe

32c heat diffuser

32d protrusions

34 fan

36 airflow guide

What is claimed is:

1. A computing device comprising:
a chassis;
a heat generating element connected to a substrate within the chassis;
a heat management system, configured to cool the heat generating element, that includes:
a heat conductor that is thermally connected to the heat generating element;
two fans configured to discharge air across the heat conductor; and
an airflow guide disposed between the two fans in a width direction of the chassis,
wherein the airflow guide thermally connects the heat conductor to the chassis.

2. The computing device according to claim 1, wherein
the airflow guide includes a thermal rubber pad.

3. The computing device according to claim 2, wherein
the thermal rubber pad has a side surface that is inclined with respect to an airflow direction of at least one of the two fans.

4. The computing device according to claim 2, wherein
the thermal rubber pad has a triangular shape.

5. The computing device according to claim 1, wherein
the airflow guide includes a plurality of thermal rubber pads.

6. The computing device according to claim 5, wherein
the plurality of thermal rubber pads are disposed to form an airflow gap therebetween.

7. The computing device of claim 1, wherein
the chassis includes:
a top cover with a keyboard;
a bottom cover opposite to the top cover in a thickness direction of the chassis;
an exhaust port, and
the airflow guide thermally and physically connects the heat conductor to the bottom cover of the chassis.

8. The computing device according to claim 7, wherein
in a plan view of the heat conductor, the airflow guide has a tapered shape such that a width of the airflow guide on a side closer to the exhaust port is smaller than a width of the airflow guide on a side farther from the exhaust port.

9. The computing device according to claim 7, wherein
in a plan view of the heat conductor, the airflow guide is disposed farther from the exhaust port than a center of the heat conductor.

10. The computing device according to claim 1, wherein
the airflow guide at least partially overlaps a heat pipe that is thermally connected to the heat generating element in a thickness direction of the chassis.

11. The computing device according to claim 1, wherein
the airflow guide at least partially overlaps a heat sink connected to the heat generating element in a thickness direction of the chassis.
